(19) United States
(12) Patent Application Publication
(10) Pub. No.: US 2019/0203552 A1
(43) Pub. Date: Jul. 4, 2019

(54) AUTOMATIC WIRELINE TUNER

(71) Applicant: Halliburton Energy Services, Inc., Houston, TX (US)

(72) Inventor: George D. Goodman, Houston, TX (US)

(73) Assignee: Halliburton Energy Services, Inc., Houston, TX (US)

(21) Appl. No.: 15/567,819

(22) PCT Filed: Sep. 23, 2016
(86) PCT No.: PCT/US16/53460

§ 371 Date: Oct. 19, 2017

(51) Int. Cl. E21B 23/14; H03H 7/40

(52) U.S. Cl. CPC E21B 23/14; H03H 7/40

(57) ABSTRACT

Disclosed herein are methods and systems that include an automatic wireline tuner. A downhole cable system may comprise a cable assembly comprising a conductor; and a negative impedance circuit at a termination of the conductor in the cable assembly.

In the production of desirable fluids (e.g., oil, gas, etc.) from subterranean formations, wellbores may be drilled that penetrate one or more subterranean formations. It is often necessary to survey or “log” the subterranean formations surrounding the wellbore by passing a logging sonde or well logging tool through the wellbore to measure the parameters or characteristics of the subterranean formations at various depths within the wellbore. The well logging tool may be passed through the wellbore using a cable assembly, often referred to as a “wireline cable,” which may supply electrical power to the well logging tool and may transmit telemetry signals between the surface and the well logging tool. The well logging tool may collect data and other information as it passes through the wellbore and may transmit the data and information to the surface for further processing and analysis.

The cable assembly on which the well logging tool is carried may comprise one or more conductors. One example is a multi-conductor cable assembly that comprises six insulated conductors wrapped around a seventh, central insulated conductor. Cable assemblies are typically long high-loss transmission lines with low bandwidths making them problematic for wide bandwidth digital-subscriber-line-type transmissions. Cable assemblies may further be impacted by variables resulting from length that has been spooled on/off the drum, the temperature gradient within the wellbore, and/or cable stretch/relaxation due to mechanical loading.

### BRIEF DESCRIPTION OF THE DRAWINGS

These drawings illustrate certain aspects of some of the embodiments of the present invention, and should not be used to limit or define the invention.

FIG. 1 is a schematic diagram of an example downhole cable system.

FIG. 2 is a schematic diagram of an example circuit illustrating a differential wireline segment.

FIG. 3 is a schematic diagram of an example circuit model illustrating voltage on the line as function of distance (x) from a signal source.

FIG. 4 is a schematic diagram of an example circuit model illustrating termination of a transmission line into a negative source impedance.

FIG. 5 is a chart illustrating relative characteristics of positive and negative resistance.

FIG. 6 is a chart illustrating relative characteristics of positive and negative capacitance.

FIG. 7 is a schematic diagram of an example circuit illustrating termination of a cable assembly into a negative impedance circuit.

FIG. 8 is a schematic diagram of another example circuit illustrating termination of a cable assembly into a negative impedance circuit.

FIG. 9 is a schematic diagram of yet another example circuit illustrating termination of a cable assembly into a negative impedance circuit.

FIG. 10 is a schematic diagram of a power delivery system for a wireline assembly, wherein the telemetry receiver includes a negative impedance circuit.

FIG. 11 is a schematic diagram of an example well monitoring system.

FIG. 12 is a chart that illustrates a negative resistance tuning response of a receiver's output.

FIG. 13 is a chart that illustrates a negative capacitance tuning response of a receiver's output.

### DESCRIPTION

Disclosed herein are methods and systems that include an automatic wireline tuner. The automatic wireline tuner may be incorporated into a downhole cable system as a negative impedance circuit. The negative impedance circuits may include electrical components arranged to emulate negative circuit elements. By incorporation of a negative impedance circuit into the termination of a cable assembly, attenuation may be minimized and bandwidth may be improved. Additionally, the negative impedance circuit may be tunable to allow for an active line termination that may match characteristics of the conductors in the cable assembly.

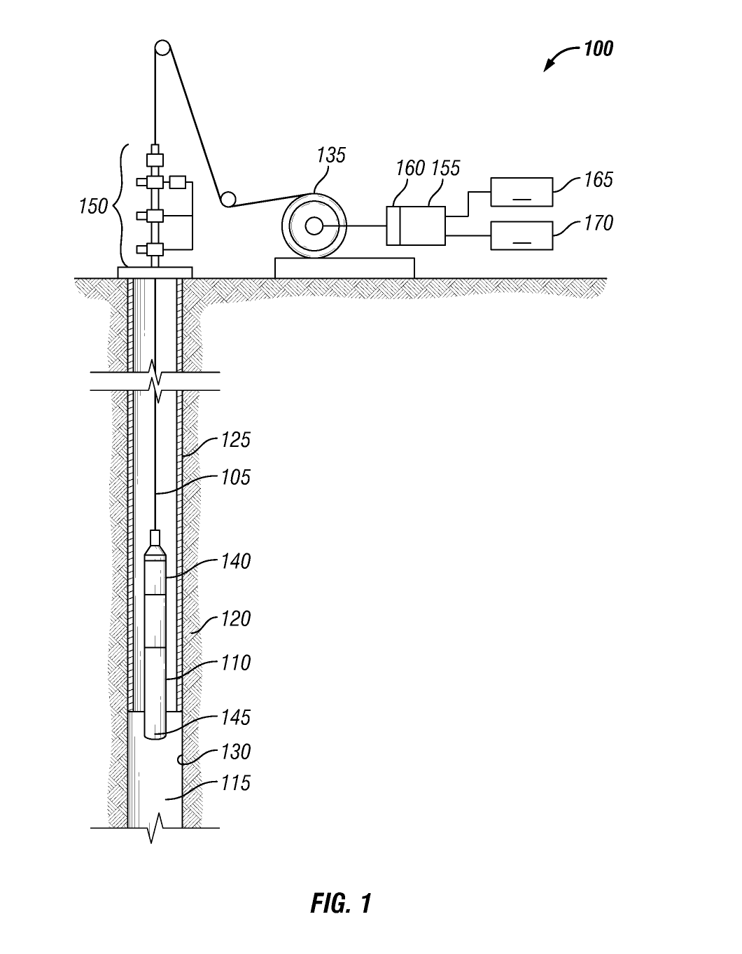

An example of a downhole cable system 100, illustrated in FIG. 1, may include a cable assembly 105 on which a downhole tool 110 may be disposed. The downhole tool 110 may take measurements and/or obtain information from the downhole environment. As illustrated, the downhole tool 110 may be disposed in a wellbore 115 that extends through one or more subterranean formations 120. The wellbore 115 may be cased, for example, with casing 125, and/or may be openhole as shown at 130. While the wellbore 115 is shown extending generally vertically into the one or more subterranean formations 120, the principles described herein are also applicable to wellbores that extend at an angle through the one or more subterranean formations 120, such as horizontal and slanted wellbores. For example, although FIG. 1 shows a vertical or low inclination angle well, high inclination angle or horizontal placement of the well and equipment is also possible. It should further be noted that while FIG. 1 generally depicts a land-based operation, those skilled in the art will readily recognize that the principles described herein are equally applicable to subsea operations that employ floating or sea-based platforms and rigs, without departing from the scope of the disclosure.

As illustrated, a hoist 135 may be used to run downhole tool 110 into wellbore 115. Hoist 135 may be installed at surface or disposed on a recovery vehicle (not shown). Hoist 135 may be used, for example, to raise and lower cable assembly 105 in wellbore 115. Downhole tool 110 may be suspended in wellbore 115 on cable assembly 105. As the downhole tool 110 is passed through the wellbore 115, information may be collected and gathered on the one or more subterranean formations 120 surrounding the wellbore 115. Downhole tool 110 may any of a various types of tools for recording downhole data. It should be appreciated that the present invention should not be limited to any specific type of downhole tool 110. As illustrated, downhole tool 110 may include electronic circuitry 140 at an upper portion of the downhole tool 110 for controlling supply of power and transmission of signals to and from the downhole tool 110, for example, including a downhole telemetry/power subassembly. Downhole tool 110 may further include an instrument portion 145 for collecting data, for example, on one or more subterranean formations 120.

As previously described, the downhole cable system 100 may include cable assembly 105. As illustrated, cable assembly 105 may extend from downhole tool 110 up through wellhead 150 to hoist 135. The conductors in cable assembly 105 may be coupled to a surface telemetry system 155. The surface telemetry system 155 may include telemetry transmitters and telemetry receivers for supply of transmission signals to and from the downhole tool. The surface telemetry system 155 may also control supply of power from surface to downhole tool 110. The surface telemetry system 155 may include a negative impedance circuit 160. The negative impedance circuit 160 may be disposed in the surface telemetry system 155 at a termination of one or more of the conductors in cable assembly 105. While FIG. 1 shows negative impedance circuit 160 at the surface, negative impedance circuit 160 may also be disposed downhole in addition to or in place of positioning at surface. For example, an additional negative impedance circuit 160 may be disposed at a termination of one or more of the conductors in cable assembly 105 at downhole tool 110. The negative impedance circuit 160 may reflect a negative impedance at its input port used to terminate the conductors. As will be discussed in more detail below, the negative impedance circuit 160 may function as negative load to constructively inject energy into the conductor termination enhancing signal reception in contrast to conventional circuit elements that consume energy. It is common to terminate conductors into electrical networks that provide a conjugate impedance match yielding only a resistive component that can be optimized for feeding the receiver circuitry. Conjugate matching circuits are tuned and are inherently narrowband solutions, whereas, the negative impedance circuit 160 may behave as if the conductor were tuned with negative resistance, capacitance and/or inductance. It is further noted that conventional line tuners terminate the conductors into its ‘real’ characteristic equivalent impedance nulling destructive signal components that are reflected back into the conductor, whereas, the negative impedance circuit 160 terminates the conductor into a negative impedance that has a magnitude that is nearly equal to the conductors characteristic impedance reflecting signals that are constructive with the signal being delivered by the line thereby enhancing their amplitudes. The negative impedance circuit 160 may be tunable in that the negative impedance circuit elements may be controlled by adjusting the values of these circuit components allowing their negative equivalent to be reflected at the port used to terminate the conductor.

Downhole cable system 100 may further include a computer 165. Computer 165 may be configured to analyze logging data from downhole tool 110 and/or provide control signals to surface telemetry system 155. Computer 165 may be coupled to surface telemetry system 155 and/or cable assembly 105. Downhole cable system 100 may further include a power supply 170 for supplying power to downhole tool 110. As illustrated, cable assembly 105 may be coupled to power supply 170 by way of surface telemetry system 155.

Cable assemblies (e.g., wireline cables), such as cable assembly 105, often comprise multiple discrete conductors. For example, cable assembly 105 may comprise from 1 to 7 (or potentially more) conductors. The conductors may be contained with an outer casing. The outer casing may comprise a material, such as steel, for bearing mechanical load and shielding the conductors from the downhole environment. In general, the conductors may be combined into orthogonal modes to allow multiple channels to be operated with minimum cross-coupling between them. Each of these mode configurations may be considered a transmission line.

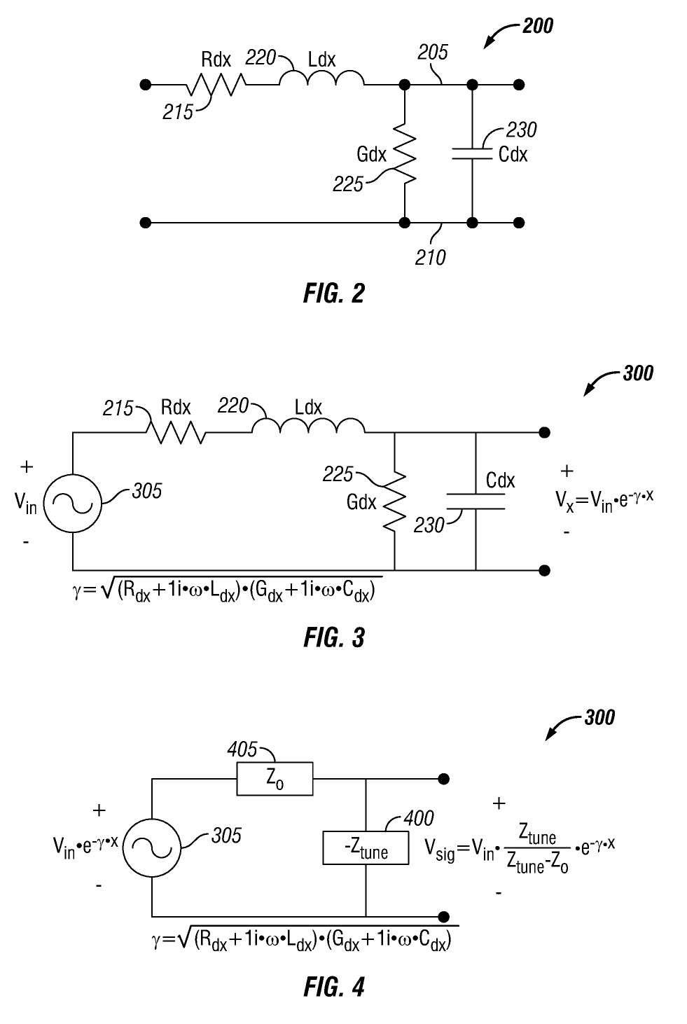

A lumped element model representing a differential segment 200 of a transmission line may be represented by FIG. 2. As previously described, the transmission line may be a combination of one or more conductors in cable assembly 105. In FIG. 2, the differential segment 200 may represent a particular transmission line with a signal line 205 and a return line 210. The signal line 205 may include a resistor 215 and an inductor 220. A shunt resistor 225 and a capacitor 230 may be positioned between the signal line 205 and the return line 210. In FIG. 1, R_{dx}, L_{dx}, G_{dx}, and C_{dx}, are respectively, the per unit length resistance, inductance, shunt conductance, and capacitance of differential segment 200. As illustrated in equation (1) below, the characteristic impedance (Zₒ) of the transmission line may be defined in terms of R_{dx}, L_{dx}, G_{dx}, and C_{dx}.

$${Z}_{o} = \sqrt{\frac{{R}_{dx} + 1 i \cdot ω \cdot {L}_{dx}}{{G}_{dx} + 1 i \cdot ω \cdot {C}_{dx}}} \qquad ( 1 )$$

Wherein Zₒ is characteristic impedance, R_{dx} is per unit length resistance, L_{dx} is per unit length inductance, G_{dx} is per unit length shunt conductance, C_{dx} is per unit length capacitance, and co is annular frequency. As illustrated in equation (2) below, the real part of the transmission line's characteristic impedance (Zₒ) may dominate the reactive component in a frequency range of interest for digital subscriber line (DSL) communications and is nearly equal to the square root of the ratio of inductance (L_{dx}) to capacitance (C_{dx}) per unit length of the transmission line.

$${lim}_{ω \to ∞} \sqrt{\frac{{R}_{dx} + 1 i \cdot ω \cdot {L}_{dx}}{{G}_{dx} + 1 i \cdot ω \cdot {C}_{dx}}} = \sqrt{\frac{{L}_{dx}}{{C}_{dx}}} \qquad ( 2 )$$

FIG. 3 illustrates an example circuit model illustrating voltage on a transmission line 300 as a function of distance (x) from a signal source 305. The circuit model present on FIG. 3 may be representative of a mono-conductor wireline (e.g., cable assembly 105 on FIG. 1) or single mode of multi-conductor wireline. The input voltage is represented by Vᵢₙ. The voltage at distance (x) is represented by Vₓ. On FIG. 3, the signal source 305 is represented as a voltage source, but other types of signal sources may be used. As the electromagnetic fields propagate along the transmission line 300, energy may be transferred by their out-of-phase components and may be attenuated by the real or in-phase components. As shown on FIG. 3, the propagation constant λ may be a function of R_{dx}, L_{dx}, G_{dx}, C_{dx}, and annular frequency (ω). Transmission lines 208 may be designed to provide a desired characteristic impedance (Zₒ) while minimizing signal attenuation as function of their length for a target frequency range. With reference to the equation shown on FIG. 3 of the propagation constant λ, it can be seen that when the reactive elements dominate that little change in signal magnitude occurs along the line's length as the signal energy cycles between electric and magnetic fields.

However, physical constrains may greatly limit design optimization of these parameters for standard configuration of cable assemblies (e.g., cable assembly 105 on FIG. 1, such as a wireline cable) that may be used for downhole well logging, for example. The break frequency between the real and reactive elements may occur at frequencies well below the desired communications data rate. As a result, signal bandwidth may be limited due to high attenuation at relatively low communication frequencies. Even further, the problem may be exacerbated as downhole tool technology continues to evolve demanding even greater data bandwidth at greater well depths.

Those of ordinary skill in the art, with the benefit of this disclosure, should recognize that the purpose of transmission lines is to deliver signals from a source to a distance location. For example, as shown on FIG. 1, the cable assembly 105 may be used to deliver signals from the surface to downhole tool, or vice versa. As a result, the transmission line 300 may need to abruptly terminate to recover information from the transmission line 300. Normally, transmission line 300 may terminate into receiver circuitry (e.g., surface telemetry system 155 on FIG. 1) that provides input impedance that may match the characteristic impedance (Zₒ) of the transmission line 300. For example, as shown on FIG. 1, the cable assembly 105 terminates at surface telemetry system 155 at the surface and at electronic circuitry 140 downhole. This design may dissipate available power delivered at the end of the transmission line 300 in the amplifier's input where it can be amplified. The line-to-receiver impedance matching may produce a “flat line” avoiding the reflection of signal power back into the transmission line 300. In downhole operations, cable assemblies (e.g., cable assembly 105 such as a wireline cable) are often designed with cable assembly 105 termination into a resistance value matching the nominal characteristics of the cable assembly 105. However, such termination techniques may yield reduced benefit when termination long lossy lines that have a larger temperature gradient over its length. The term “lossy” line generally refers to a line where R_{dx}, and G_{dx} are not 0. Cable assemblies (e.g., cable assembly 105 such as a wireline cable) used in downhole assemblies may be considered lossy lines.

FIG. 4 is an example circuit model illustrating termination of transmission line 300 into a negative load impedance (−Zₜᵤₙₑ) represented as reference number 400. Signal source 305 may input a signal (Vᵢₙ) into transmission line 300, which may be a voltage with propagation constant (γ) and length (x), for example. The characteristic impedance (Zₒ) is illustrated at reference number 405. The transmission line 300 may be represented by its Thevenin equivalent model comprising an attenuated signal that is sourced from the characteristic impedance 405. A high loss cable assembly (e.g., cable assembly 105 on FIG. 1, such as a wireline cable) may add additional complexity, as illustrated by the model shown on FIG. 4. The source impedance is a function of characteristic impedance 405 and the net propagation constant (γ) over the length of the transmission line 300. The characteristic impedance 405 and the impedance resulting from the propagation constant (γ) may have variability with total line length, the line length spooled from the drum (e.g., hoist 135 on FIG. 1), mechanical load stretching, bottomhole temperature, and temperature gradient over the length of the wellbore (e.g., wellbore 115 on FIG. 1). Due to this variability, the load match for the negative load impedance 400 may need to be adaptive or automatically tuned to the characteristics of the transmission line 300.

Even further, as shown by the circuit model illustrated on FIG. 4, the downhole signal level may peak when the characteristic impedance 405 is nulled with the negative load impedance 400. Transmission lines (e.g., transmission line 300) may be terminated through L/C matching networks configured as L-section or pi-sections with two ports. These L/C matching networks may be impedance transformers used to null capacitive reactance with inductive reactance, or the opposite, and to transform real resistance to a new value. However, these techniques may be narrowband and downhole applications may require multi-communication tones spread over a wide frequency range to support DSL-type communications. Accordingly, it may be advantageous to null the source impedance of transmission line 300 with anti-circuit elements that provide equal but opposite characteristics over the full frequency range.

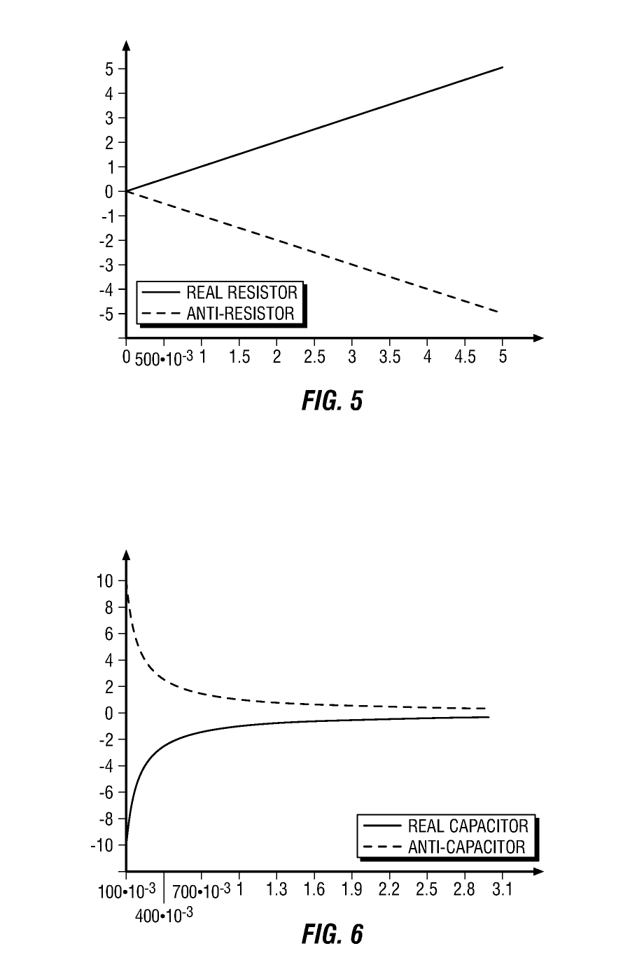

Referring now to FIGS. 5 and 6, charts are provided showing relative characteristics of positive and negative resistance and relative characteristics of positive and negative capacitances, respectively. In FIG. 5, the resistance current versus voltage characteristics is shown normalized for 1 Ohm. The solid line represents a positive or real resistor. As illustrated, the current increases and the real resistor dissipates power as voltage increases. The dashed line represents a negative or anti-resistor (e.g., −1 Ohms of resistance). As illustrated, the anti-resistor sources current and power as the voltage increases. FIG. 6 provides the frequency response for a positive or real capacitor (solid line) along with the frequency response for a negative or anti-capacitor (dashed line). As illustrated, the anti-capacitor has the same impedance magnitude as the real capacitor, unlike an inductor, its reactance is always 180° out of phase with the real capacitor at all frequencies. Accordingly, it may be advantageous to select or tune the negative circuit elements terminating the transmission line 300 such that they reflect a complex power, real and reactive components, into the transmission line 300 that is constructive to the signal that is to be detected.

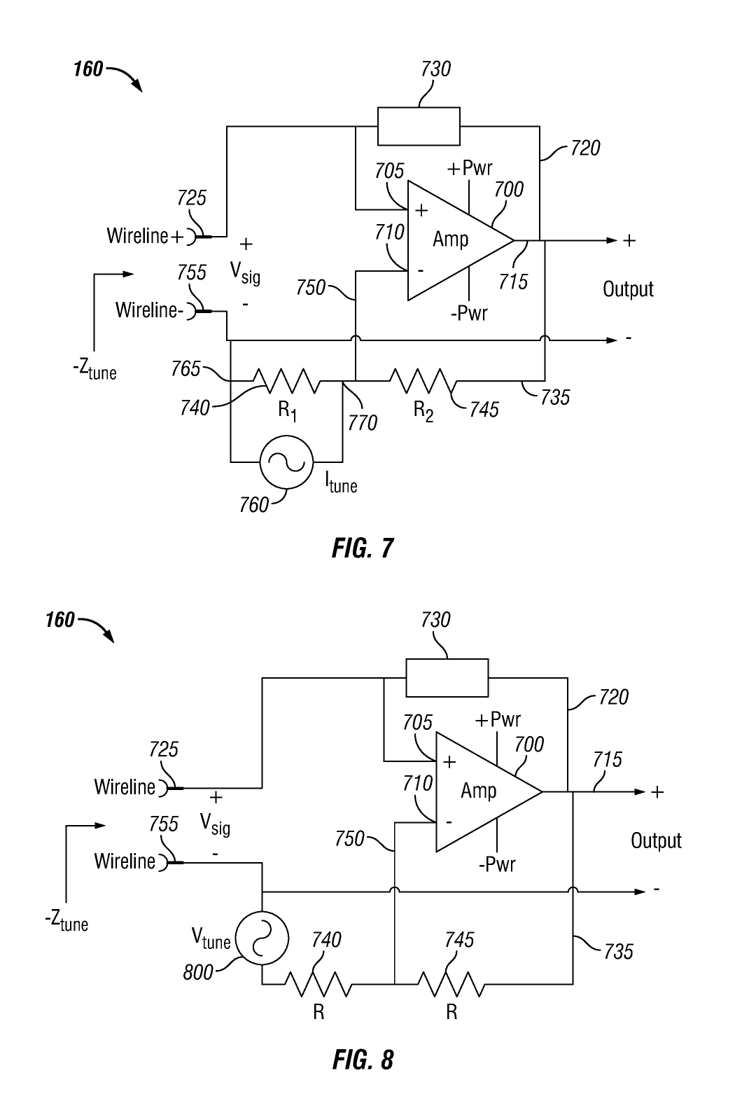

FIG. 7 illustrates an example of a negative impedance circuit 160. As illustrated, the negative impedance circuit 160 may be placed at the termination of a cable assembly (e.g., cable assembly 105 on FIG. 1, such as a wireline cable), with its signal represented on FIG. 5 as V_{sig}. The input impedance of the negative impedance circuit 160 is designated Zₜᵤₙₑ. By way of example, the negative impedance circuit 160 may be configured as the input of a wireline receiver (e.g., surface telemetry system 155 on FIG. 1), which may be either uphole or downhole. The negative impedance circuit 160 may include an amplifier 700. Amplifier 700 may include a positive amplifier input 705, a negative amplifier input 710, and an amplifier output 715. Amplifier output 715 may include a positive feedback path 720. Positive feedback path 720 may include an impedance controller 730 (Zₜᵤₙₑ). As illustrated, positive feedback path 720 may combined with a positive terminal 725 of V_{sig} and be fed to the positive amplifier input 705. Impedance controller 730 may be implemented as any number of circuit elements in positive feedback path 720. By way of example, the impedance controller 730 may include one or more potentiometers, resistors, capacitors, and/or inductors. The impedance provided by the circuit elements disposed in the positive feedback path 720 may be controlled such that the Zₜᵤₙₑ may be tunable. A microprocessor (e.g., digital signal processing) or other suitable processing element may control the circuit elements, for example, using analog switches, to achieve the desired impedance values in the positive feedback path 720. The desired impedance values may be determined, for example, by use of a tuning algorithm, wherein the microprocessor may emulate the negative impedance by injecting constructive currents back into the line while closing the control loop via analog-to-digital convertor feedback.

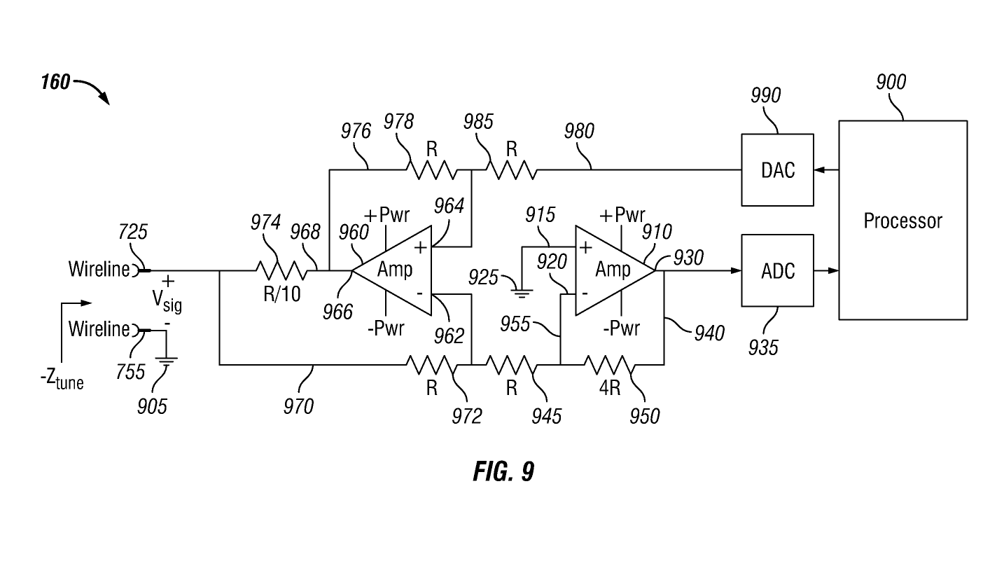

Amplifier output 715 may also include a negative feedback path 735. The negative feedback path 735 may include a first resistor 740 (R₁) and a second resistor 745 (R₂) coupled in series. First resistor 740 and second resistor 745 may have a resistance that is the same or different. A tap 750 between the first resistor 740 and the second resistor 745 may be coupled to negative amplifier input 710. The negative feedback path 735 may be coupled to negative terminal 755 of V_{sig}. To facilitate control of Zₜᵤₙₑ, a tuning signal may be injected. As illustrated, a signal modulator, such as current modulator 760, may be used to inject a tuning signal. Without limitation, signal modulator may be a current modulator 760 or a voltage modulator. On FIG. 7, the signal modulator may be a current modulator 760, and the tuning signal may be represented as Iₜᵤₙₑ. As desired, the tuning signal Iₜᵤₙₑ may be a single tone, a multi-tone, a frequency chirp pulse, or other suitable implementation as desired for a particular implementation. A tuning signal Iₜᵤₙₑ that is multi-toned may allow the digital signal processor to select the optimal tuning for a range of frequencies. Yet another implementation may be to implement the tuning signal Iₜᵤₙₑ as a frequency chirp pulse when a continuum of frequencies may be desired. As illustrated, the tuning signal Iₜᵤₙₑ may be injected into one of two summing junctions 765, 775 in the negative feedback path 735. The signal modulator (e.g., current modulator 760) may be controlled, for example, by use of the microprocessor's numerically controlled oscillator or other suitable means. It should be understood that the negative impedance circuit 160 shown on FIG. 7 is merely exemplary and other suitable elements for inputting negative impedance may be used without departing the intended scope. By way of example, the signal modulator (e.g., current modulator 760) may be placed in shunt with terminals of the wireline. Alternatively, signal modulator may be implemented as a voltage source and placed, for example, in series with the negative impedance circuit 160 and the wireline or in series with first resistor 740 and second resistor 745 in negative feedback path 735 of amplifier 700. Even further, the negative impedance circuit 160 may be implemented in software, for example, disposed with the processing element (e.g., a digital signal processor) while incorporating current and voltage sensors and driver means (e.g., an operational amplifier such as second amplifier 330 on FIG. 9) for emulating the negative impedance and frequency response. Additional implementations of the negative impedance circuit 160 may include devices that provide negative incremental impedances when operated within certain regions of their current-voltage response. Examples of such devices may include, without limitation, gunn diodes, gas discharge tubs, and neon lamps.

In operation, the output signal may be monitored while injecting a test signal using the signal modulator while adjusting the resistive component of impedance controller 730. By way of example, the resistive component part of impedance controller 730 may be adjusted to receive optimum signal peaking within stability constraints. The reactive component parts of impedance controller 730 may be adjusted to achieve, for example, optimum broadband performance. The tuning signal may be a signal target frequency needed to achieve a desired data bandwidth or more advanced algorithms may sweep the tuning signal's frequency to further optimize useable bandwidth and/or passband flatness. The tuning signal may be varied, for example, in response to a detected signal falling below a preset threshold.

FIG. 8 illustrates another example of a negative impedance circuit 160. As illustrated on FIG. 8, signal modulator in the form of a voltage modulator 800 may be placed in series with first resistor 740 and second resistor 745 in negative feedback path 735 of amplifier 700. On FIG. 8, the tuning signal may be represented as Vₜᵤₙₑ.

FIG. 9 illustrates yet another example of a negative impedance circuit 160 that implements a processor 900. Processor 900 may include a microprocessor, such as a digital signal processor, or other suitable processing element. As illustrated, the negative impedance circuit 160 may be placed at the termination of a cable assembly (e.g., cable assembly 105 on FIG. 1, such as a wireline cable), with its signal represented on FIG. 9 as V_{sig}. The input impedance of the negative impedance circuit 160 is designated Zₜᵤₙₑ. The negative terminal 755 of V_{sig} may be coupled to a first ground 905. Without limitation, the negative impedance circuit 160 may comprise a first amplifier 910. First amplifier 910 may comprise a first amplifier positive input 915, first amplifier negative input 920, and first amplifier output 930. First amplifier positive input 915 may be coupled to a second ground 925, which may be the same or different than first ground 905. First amplifier output 930 may be coupled to an analog-to-digital converter 935 that feeds processor 900. First amplifier output 930 may include a first amplifier negative feedback path 940. The first amplifier negative feedback path 940 may include a first feedback resistor 945 and a second feedback resistor 950 coupled in series. First feedback resistor 945 and second feedback resistor 950 may have a resistance that is the same or different. By way of example, second feedback resistor 950 may have resistance that is four time the resistance of first feedback resistor 945, as indicated in FIG. 9. A first feedback tap 955 between the first feedback resistor 945 and the second feedback resistor 950 may be coupled to first amplifier negative input 920.

Without limitation, negative impedance circuit 160 may further include a second amplifier 960. Second amplifier 960 may comprise a second amplifier positive input 962, second amplifier negative input 964, and second amplifier output 966. Second amplifier positive input 962 may be coupled to positive terminal 725 of V_{sig} by first connector line 970. Second amplifier input resistor 972 may be disposed in first connector line 970. Second amplifier input resistor 972 may have a resistance that is the same or different than first feedback resistor 945 and second feedback resistor 950. As illustrated, second amplifier input resistor 972 may have a resistance that is the same as first feedback resistor 945. Without limitation, first connector line 970 may combine with first amplifier negative feedback path 940 and feed into second amplifier positive input 962. Second amplifier output 966 may be coupled to positive terminal 725 of V_{sig} by second connector line 968. Second amplifier output 966 may further include second amplifier output resistor 974. Second amplifier output resistor 974 may have a resistance that is the same or different than the other resistors (e.g., first feedback resistor 945, second feedback resistor 950, etc.) in the negative impedance circuit 160. As illustrated, second amplifier output resistor 974 may have a resistance that is 1/10 a resistance of first feedback resistor 945. Second amplifier output 966 may further include a second amplifier negative feedback path 976. Second amplifier feedback resistor 978 may be disposed in second amplifier negative feedback path 976. Second amplifier feedback resistor 978 may have a resistance that is the same or different than the other resistors (e.g., first feedback resistor 945, second feedback resistor 950, etc.) in the negative impedance circuit 160. As illustrated, second amplifier feedback resistor 978 may have a resistance that is the same as first feedback resistor 945.

As illustrated, second amplifier negative feedback path 976 may combine with a current injection line 980 and then feed second amplifier negative input 964. Current injection line 980 may include a current injection resistor 985. Current injection resistor 985 may have a resistance that is the same or different than the other resistors (e.g., first feedback resistor 945, second feedback resistor 950, etc.) in the negative impedance circuit 160. As illustrated, current injection resistor 985 may have a resistance that is the same as first feedback resistor 945. Current injection line 980 may receive a current signal from processor 900 by way of digital to analog converter 990. The tuning algorithm may determine, for example, the negative circuit elements to be emulated.

It should be noted that, for the equation for V_{sig} shown on FIG. 4, a singularity may result when Zₜᵤₙₑ is equal to Zₒ. The negative impedance circuit 160 combined with a cable assembly 105 may form a positive feedback system making it potentially prone to oscillation. Accordingly, at least 6 dB or more in separation between the receiver input impedance and the particular conductor's characteristic impedance may needed after tuning; however, the invention should not be limited to this particular implementation.

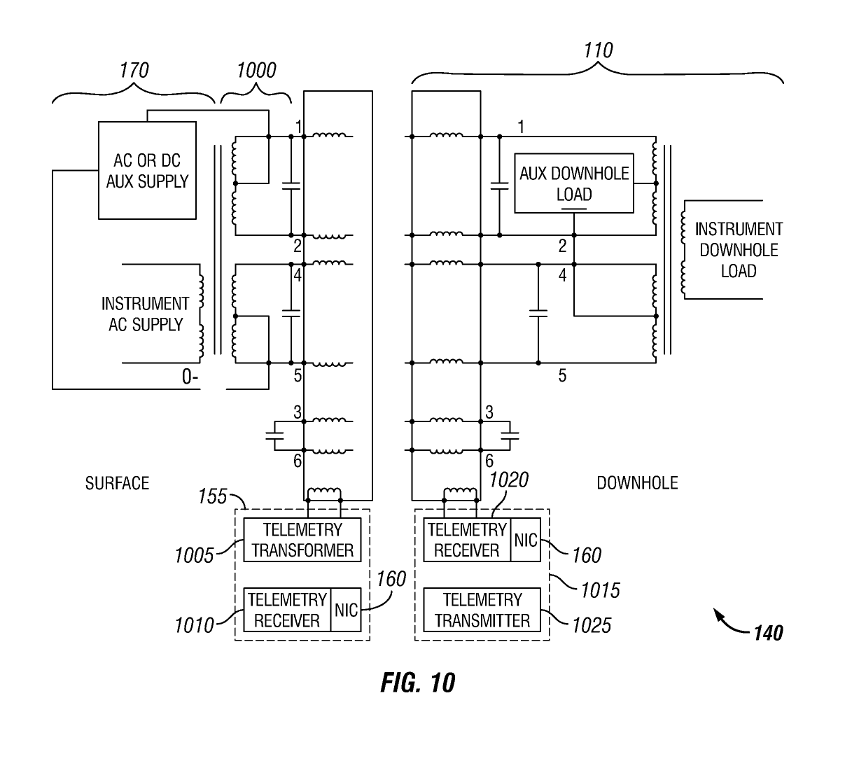

FIG. 10 is a schematic showing implementation of one or more negative impedance circuits 160. Illustrated on FIG. 10 are six conductors of a cable assembly (e.g., cable assembly 105 shown on FIG. 1) that are labeled with reference numbers 1-6, respectively. As illustrated, conductors 1-6 may be coupled to power supply 170 by way of transformer 1000. Conductors 1-6 may also be coupled to surface telemetry system 155, which may comprise surface telemetry transformer 1005 and surface telemetry receiver 1010. Without limitation, surface telemetry receiver 1010 may include the negative impedance circuit 160. By way of example, the input of surface telemetry receiver 1010 may be configured as negative impedance circuit 160. Also illustrated on FIG. 10 is downhole tool 110, which may comprise electronic circuitry 140. As illustrated, conductors 1-6 may be coupled to electronic circuitry 140 of downhole tool 110. Electronic circuitry 140 of downhole tool 110 may comprise a downhole telemetry system 1015, which may comprise a downhole telemetry receiver 1020 and downhole telemetry transmitter 1025. Downhole telemetry receiver 1020 may connect a surface system (e.g., surface telemetry system 155) with downhole tool 110 or system. Without limitation, downhole telemetry system 1015 may comprise a negative impedance circuit 160, which may be in addition to or in place of negative impedance circuit 160 disposed in surface telemetry system 155. Downhole telemetry receiver 1020 may include the negative impedance circuit 160. By way of example, the input of downhole telemetry receiver 1020 may be configured as negative impedance circuit 160. It should be understood that the particular implementation shown on FIG. 10 is merely illustrative and that negative impedance circuit 160 may be implemented in a different manner, as would be appreciated by those of ordinary skill in the art.

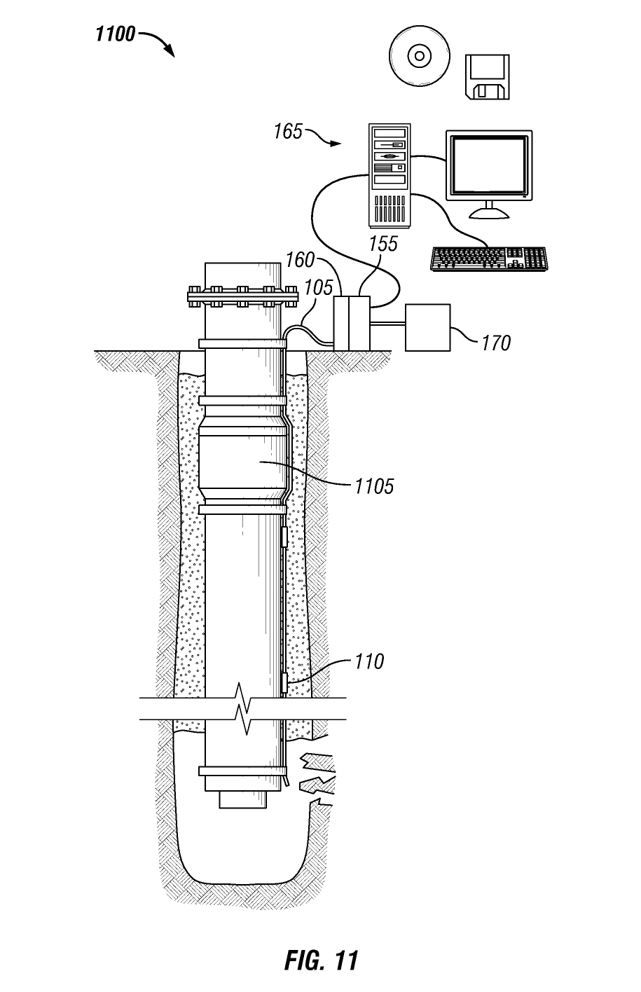

FIG. 11 is a schematic diagram showing use of negative impedance circuit 160 in well monitoring system 1100. In FIG. 11, well monitoring system 1100 may include downhole cable system 100, which may comprise cable assembly 105. As illustrated, cable assembly 105 may connect to downhole tool 110, which may be any type of suitable tool. Downhole tool 110 and cable assembly 105 may be disposed outside of casing 1105. As illustrated, cable assembly 105 may be disposed on the outside of casing 1105. In examples, cable assembly 105 may be coupled within casing 1105, either by attachment to the production tubing or attachment to the internal portion of casing 1105. Surface telemetry system 155 may be coupled to cable assembly 105 in order to transmit a signal downhole. Negative impedance circuit 160 may be a component of surface telemetry system 155, for example, an input to a telemetry receiver (e.g., surface telemetry receiver 1010 on FIG. 10). Computer 165 and power supply 170 may also be coupled to surface telemetry system 155.

An example may comprise a downhole cable system that may comprise a cable assembly comprising a conductor, and a negative impedance circuit at a termination of the conductor in the cable assembly. The downhole cable system may comprise any of the following features in any combination. The downhole cable system may comprise a downhole tool coupled to the cable assembly, wherein the downhole tool receives power, receives signals, and/or transmits signals via the cable assembly. The negative impedance circuit may be configured as part of an input for a downhole telemetry receiver for connecting a surface system with a downhole tool or system. The cable assembly may extend into a wellbore, wherein the negative impedance circuit is disposed at a surface of the wellbore. The negative impedance circuit may be configured as an input of a surface telemetry receiver. The downhole cable system may further comprise a surface telemetry system that controls supply of power and transmission signals from a surface of a wellbore to a downhole tool coupled to the cable assembly, wherein the surface telemetry system comprises the negative impedance circuit. The negative impedance circuit may be configured to provide a tunable negative load impedance to the conductor. The negative impedance circuit may comprise an amplifier, wherein the amplifier comprises a positive input, a negative input, and an output. The negative impedance circuit may further comprise a positive feedback path for the amplifier, wherein the positive feedback path comprises an impedance controller, wherein the positive feedback path combines with a positive terminal of the cable assembly to feed the positive input of the amplifier. The negative impedance circuit may further comprise a negative feedback path for the amplifier comprising a first resistor and a second resistor coupled in series with the first resistor, wherein a tap between the first resistor and the second resistor feeds the negative input of the amplifier, wherein the negative feedback path is coupled to a negative terminal of the cable assembly. The negative impedance circuit may further comprise a signal modulator operable to input a tuning signal into the negative impedance circuit. The signal modulator may be a current modulator operable to inject the tuning signal into a summing junction in the negative feedback path. The signal modulator may be a voltage modulator in series with the negative impedance circuit. The impedance controller may comprise at least one circuit element selected from resistors, potentiometers, capacitors, and inductors. The negative impedance circuit may comprise a first amplifier, wherein the first amplifier comprises a first amplifier positive input, a first amplifier negative input, and a first amplifier output, wherein the first amplifier positive input is coupled to a second ground, wherein a negative terminal of the cable assembly is coupled to a first ground, wherein first amplifier output is coupled to a processor by way of an analog-to-digital converter. The negative impedance circuit may further comprise. The negative impedance circuit may further comprise a first amplifier negative feedback path comprising a first feedback resistor and a second feedback resistor in series, wherein a first feedback tap between the first feedback resistor and the second feedback resistor is coupled to the first amplifier negative input. The negative impedance circuit may further comprise a second amplifier comprising a second amplifier positive input, a second amplifier negative input, and as second amplifier output, wherein second amplifier positive input is coupled to a positive terminal of the cable assembly by a line with a second amplifier input resistor disposed in the line, wherein the second amplifier output comprises a second amplifier output resistor and is coupled to the positive terminal of the cable assembly. The negative impedance circuit may further comprise a second amplifier negative feedback path, wherein the second amplifier negative feedback path comprises a second amplifier feedback resistor. The negative impedance circuit may further comprise a current injection line, wherein the current injection line comprises a current injection resistor, wherein the current injection line combines with the second amplifier negative feedback path and feeds the second amplifier negative input, wherein the current injection line is operable to receive a current signal from the processor by way of a digital to analog converter.

An example may comprise a system, wherein the system comprise: a cable assembly comprising a conductor; and a negative impedance circuit at a termination of the conductor in the cable assembly; a downhole tool disposed in a wellbore and coupled to the cable assembly; a surface telemetry system that controls supply of power and transmission signals from a surface of the wellbore to the downhole tool, wherein the surface telemetry system is coupled to the cable assembly; a power supply coupled to the surface telemetry system; and a computer coupled to the surface telemetry system. The system may comprise any of the following elements in any combination. The negative impedance circuit may be configured as an input of a downhole telemetry receiver for the downhole tool. The negative impedance circuit may be configured as an input of a surface telemetry receiver in the surface telemetry system. The negative impedance circuit may be configured to provide a tunable negative load impedance to the conductor. The negative impedance circuit may comprise an amplifier, wherein the amplifier comprises a positive input, a negative input, and an output. The negative impedance circuit may further comprise a positive feedback path for the amplifier, wherein the positive feedback path comprises an impedance controller, wherein the positive feedback path combines with a positive terminal of the cable assembly to feed the positive input of the amplifier. The negative impedance circuit may further comprise a negative feedback path for the amplifier comprising a first resistor and a second resistor coupled in series with the first resistor, wherein a tap between the first resistor and the second resistor feeds the negative input of the amplifier, wherein the negative feedback path is coupled to a negative terminal of the cable assembly. The negative impedance circuit may further comprise a signal modulator operable to input a tuning signal into the negative impedance circuit.

An example may comprise a method for operating a cable assembly, comprising: disposing the cable assembly in a wellbore, wherein the cable assembly comprises a conductor; transmitting a signal via the conductor in the cable assembly; and applying a tuning signal into a negative impedance circuit at a termination of the conductor to provide a negative load impedance to the conductor. The method may comprise any of the following elements in any combination. The tuning signal may be applied downhole at an input of downhole telemetry receiver of a downhole tool or the tuning signal is applied at an input of a surface telemetry receiver. The tuning signal may be varied in response to a detected signal falling below a preset threshold.

To facilitate a better understanding of the present disclosure, the following examples of certain aspects of some of the systems and methods are given. In no way should the following examples be read to limit, or define, the entire scope of the disclosure.

### Examples

The following hypothetical example was performed for tuning the receive termination of a wireline cable having a length of 40,000 foot. The wireline cable was a 7Q49-EHS cable. Typical per-unit-length properties of the wireline cable may be as follows:

$${C}_{o} := 27 \frac{pF}{ft} ;$$

$${R}_{o} := 2 \cdot 9.8 \frac{m Ω}{ft} ;$$

$${L}_{o} = 67.5 \frac{nH}{ft} ; and$$

Dissipation Factor, per ASTM D150, in frequency range of 10²-10⁶ Hz=0.001 (insulation separating the wires.

Tuning is initiated when either a reduction in data rate is detected or tuning is prompted by a significant change in the operating environment (e.g., temperature, depth, or mechanical loading), or at regular time intervals. The wireline cable was tuned using a negative impedance circuit 160, as illustrated on FIG. 7. For this example, the impedance controller 730 on FIG. 7 was configured as a series resistor and capacitor. The signal modulator 265 on FIG. 7 was configured as a current modulator that was activated with a single tone at 1 MHz. This frequency was selected for the example because the current maximum usable frequency is limited to about 500 kHz. After this system is properly tuned, optimal performance may be expected within an octave below to an octave above the tuning frequency and beyond. The tuning signal Iₜᵤₙₑ injected by the signal modulator 365 may also be multi-toned to allow the digital signal processor to select the optimal tuning for a range of frequencies. Yet another implementation may be to implement the tuning signal Iₜᵤₙₑ as frequency chirp pulse when a continuum of frequencies may be desired.

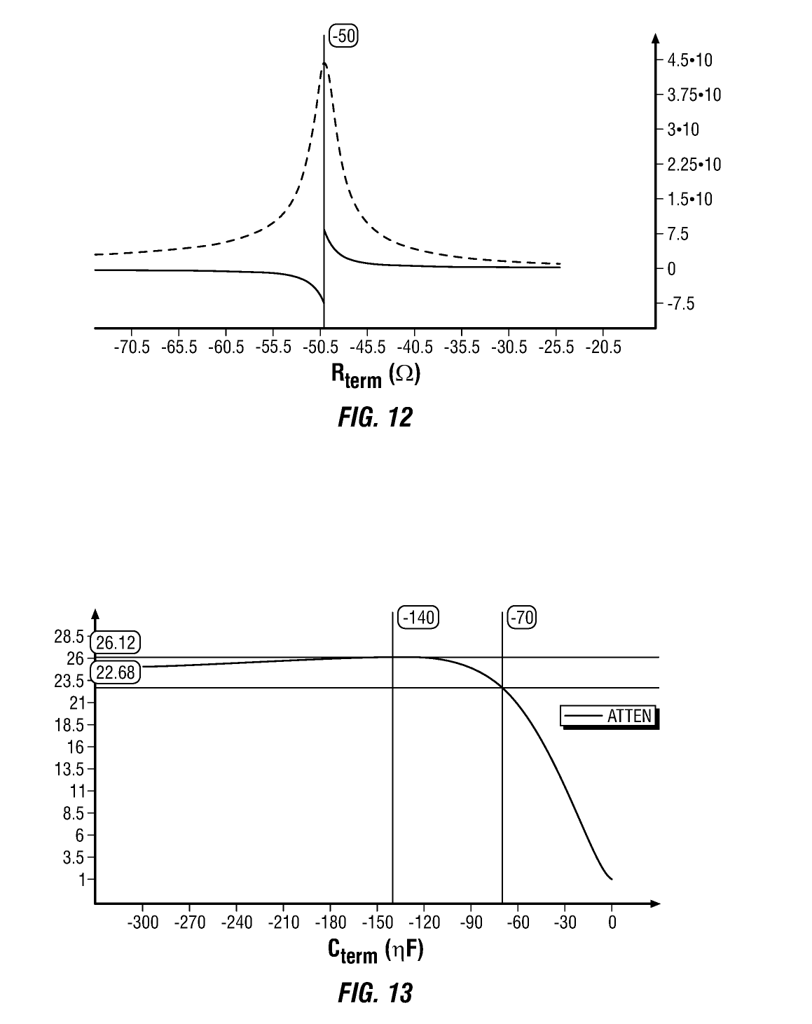

The resistance value of the resistor in impedance controller 730 may first be tuned since it may be the dominant element in combination with the capacitor. The capacitor may be initially set to its maximum value or potentially replaced with a short circuit. In this example, the resistance value was initially set to 75 Ohm and is decremented while observing the 1 MHz tone at the receiver's output. The output response of the receiver is plotted on FIG. 12. As illustrated, the output signal amplitude is shown as a dashed line, and its phase is a solid line. When the best match between the source resistance and the negative resistance of the negative impedance circuit 160 is obtained, it results in a sharp phase excursion. In this Example, −52 Ohm is selected since it provides the target 6 dB of margin as determined by the digital signal processor's resistor sweep algorithm.

For the next tuning step, the −52 Ohm value may be fixed with the series resistor-capacitor combination. On FIG. 13, the receiver's amplitude response as a function of capacitor value is plotted. As the capacitor value decreases, a peak in the calibration signal's response is observed by a rapid fall off with increasing values. The peak value (−140 nF) is the optimum termination match. However, the algorithm selects half this value (−70 nF) to provide improved stability, reduce sensitivity to noise injection, and to potentially flatten the tuned passband response.

The preceding description provides various embodiments of systems and methods of use which may contain different method steps and alternative combinations of components. It should be understood that, although individual embodiments may be discussed herein, the present disclosure covers all combinations of the disclosed embodiments, including, without limitation, the different component combinations, method step combinations, and properties of the system.

It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the element that it introduces.

Therefore, the present embodiments are well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Although individual embodiments are discussed, the invention covers all combinations of all those embodiments. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative embodiments disclosed above may be altered or modified and all such variations are considered within the scope and spirit of the present invention. If there is any conflict in the usages of a word or term in this specification and one or more patent(s) or other documents that may be incorporated herein by reference, the definitions that are consistent with this specification should be adopted.

What is claimed is:

1. A downhole cable system comprising:
a cable assembly comprising a conductor; and
a negative impedance circuit at a termination of the conductor in the cable assembly.

2. The downhole cable system of claim 1, further comprising a downhole tool coupled to the cable assembly, wherein the downhole tool receives power, receives signals, and/or transmits signals via the cable assembly.

3. The downhole cable system of claim 1, wherein the negative impedance circuit is configured as part of an input for a downhole telemetry receiver for connecting a surface system with a downhole tool or system.

4. The downhole cable system of claim 1, wherein the cable assembly extends into a wellbore, wherein the negative impedance circuit is disposed at a surface of the wellbore.

5. The downhole cable system of claim 4, wherein the negative impedance circuit is configured as an input of a surface telemetry receiver.

6. The downhole cable system of claim 1, further comprising a surface telemetry system that controls supply of power and transmission signals from a surface of a wellbore to a downhole tool coupled to the cable assembly, wherein the surface telemetry system comprises the negative impedance circuit.

7. The downhole cable system of claim 1, wherein the negative impedance circuit is configured to provide a tunable negative load impedance to the conductor.

8. The downhole cable system of claim 1, wherein the negative impedance circuit comprises:
an amplifier, wherein the amplifier comprises a positive input, a negative input, and an output;
a positive feedback path for the amplifier, wherein the positive feedback path comprises an impedance controller, wherein the positive feedback path combines with a positive terminal of the cable assembly to feed the positive input of the amplifier;
a negative feedback path for the amplifier comprising a first resistor and a second resistor coupled in series with the first resistor, wherein a tap between the first resistor and the second resistor feeds the negative input of the amplifier, wherein the negative feedback path is coupled to a negative terminal of the cable assembly; and
a signal modulator operable to input a tuning signal into the negative impedance circuit.

9. The downhole cable system of claim 8, wherein the signal modulator is a current modulator operable to inject the tuning signal into a summing junction in the negative feedback path.

10. The downhole cable system of claim 8, wherein the signal modulator is a voltage modulator in series with the negative impedance circuit.

11. The downhole cable system of claim 8, wherein the impedance controller comprises at least one circuit element selected from resistors, potentiometers, capacitors, and inductors.

12. The downhole cable system of claim 1, wherein the negative impedance circuit comprises:
a first amplifier, wherein the first amplifier comprises a first amplifier positive input, a first amplifier negative input, and a first amplifier output, wherein the first amplifier positive input is coupled to a second ground, wherein a negative terminal of the cable assembly is coupled to a first ground, wherein first amplifier output is coupled to a processor by way of an analog-to-digital converter;
a first amplifier negative feedback path comprising a first feedback resistor and a second feedback resistor in series, wherein a first feedback tap between the first feedback resistor and the second feedback resistor is coupled to the first amplifier negative input;
a second amplifier comprising a second amplifier positive input, a second amplifier negative input, and as second amplifier output, wherein second amplifier positive input is coupled to a positive terminal of the cable assembly by a line with a second amplifier input resistor disposed in the line, wherein the second amplifier output comprises a second amplifier output resistor and is coupled to the positive terminal of the cable assembly;
a second amplifier negative feedback path, wherein the second amplifier negative feedback path comprises a second amplifier feedback resistor; and
a current injection line, wherein the current injection line comprises a current injection resistor, wherein the current injection line combines with the second amplifier negative feedback path and feeds the second amplifier negative input, wherein the current injection line is operable to receive a current signal from the processor by way of a digital to analog converter.

13. A system comprising:
a cable assembly comprising a conductor;
a negative impedance circuit at a termination of the conductor in the cable assembly;
a downhole tool disposed in a wellbore and coupled to the cable assembly;
a surface telemetry system that controls supply of power and transmission signals from a surface of the wellbore to the downhole tool, wherein the surface telemetry system is coupled to the cable assembly;
a power supply coupled to the surface telemetry system; and
a computer coupled to the surface telemetry system.

14. The system of claim 13, wherein the negative impedance circuit is configured as an input of a downhole telemetry receiver for the downhole tool.

15. The system of claim 13, wherein the negative impedance circuit is configured as an input of a surface telemetry receiver in the surface telemetry system.

16. The system of claim 13, wherein the negative impedance circuit is configured to provide a tunable negative load impedance to the conductor.

17. The system of claim 13, wherein the negative impedance circuit comprises:
an amplifier, wherein the amplifier comprises a positive input, a negative input, and an output;
a positive feedback path for the amplifier, wherein the positive feedback path comprises an impedance controller, wherein the positive feedback path combines with a positive terminal of the cable assembly to feed the positive input of the amplifier;
a negative feedback path for the amplifier comprising a first resistor and a second resistor coupled in series with the first resistor, wherein a tap between the first resistor and the second resistor feeds the negative input of the amplifier, wherein the negative feedback path is coupled to a negative terminal of the cable assembly; and
a signal modulator operable to input a tuning signal into the negative impedance circuit.

18. A method for operating a cable assembly, comprising:
disposing the cable assembly in a wellbore, wherein the cable assembly comprises a conductor;
transmitting a signal via the conductor in the cable assembly; and
applying a tuning signal into a negative impedance circuit at a termination of the conductor to provide a negative load impedance to the conductor.

19. The method of claim 18, wherein the tuning signal is applied downhole at an input of downhole telemetry receiver of a downhole tool or the tuning signal is applied at an input of a surface telemetry receiver.

20. The method of claim 18, further comprising varying the tuning signal in response to a detected signal falling below a preset threshold.
